(19) United States
(12) Patent Application Publication
(10) Pub. No.: US 2023/0198501 A1
(43) Pub. Date: Jun. 22, 2023

(54) BULK ACOUSTIC RESONATOR PACKAGE

(71) Applicant: SAMSUNG ELECTRO-MECHANICS CO., LTD., Suwon-si (KR)

(72) Inventors: Dong Hoe KIM, Suwon-si (KR); Yoon Sok PARK, Suwon-si (KR); Tae Kyung LEE, Suwon-si (KR); Jeong A KIM, Suwon-si (KR)

(73) Assignee: SAMSUNG ELECTRO-MECHANICS CO., LTD., Suwon-si (KR)

(21) Appl. No.: 17/989,198

(22) Filed: Nov. 17, 2022

(30) Foreign Application Priority Data
Dec. 21, 2021 (KR) 10-2021-0183628

(51) Int. Cl. H03H 9/205; H03H 9/13

(52) U.S. Cl. CPC H03H 9/205; H03H 9/13; H03H 9/568

(57) ABSTRACT

A bulk acoustic resonator package includes a substrate, a cap, and first and second bulk acoustic resonators each including a first electrode, a piezoelectric layer, and a second electrode stacked in a direction in which the substrate and the cap face each other, and disposed between the substrate and the cap, wherein the first and second bulk acoustic resonators form a bandwidth based on first and second resonant frequencies different from each other and first and second antiresonant frequencies different from each other, a difference between the first and second resonant frequencies exceeds 200 MHz, the first bulk acoustic resonator is disposed closer to the substrate than to the cap, and the second bulk acoustic resonator is disposed closer to the cap than to the substrate.

### CROSS-REFERENCE TO RELATED APPLICATIONS

This application claims the benefit under 35 USC 119(a) of Korean Patent Application No. 10-2021-0183628 filed on Dec. 21, 2021, in the Korean Intellectual Property Office, the entire disclosure of which is incorporated herein by reference for all purposes.

### BACKGROUND

### 1. Field

The present disclosure relates to a bulk acoustic resonator package.

### 2. Description of the Background

Small and lightweight filters, oscillators, resonant elements, acoustic resonant mass sensors, etc. may be used in such devices as mobile communications devices, chemical and biological testing devices, etc.

Bulk acoustic resonators may be configured as units implementing such small and lightweight filters, oscillators, resonator elements, and acoustic resonant mass sensors, and have very small and high performance, compared to dielectric filters, metal cavity filters, wave guides, etc., so that bulk acoustic resonators may be used in communications modules of modern mobile devices requiring high performance (e.g., high quality factor, small energy loss, and wide pass bandwidth).

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a bulk acoustic resonator package includes a substrate, a cap, and first and second bulk acoustic resonators each including a first electrode, a piezoelectric layer, and a second electrode stacked in a direction in which the substrate and the cap face each other, and disposed between the substrate and the cap, wherein the first and second bulk acoustic resonators form a bandwidth based on first and second resonant frequencies different from each other and first and second antiresonant frequencies different from each other, wherein a difference between the first and second resonant frequencies exceeds 200 MHz, wherein the first bulk acoustic resonator is disposed closer to the substrate than to the cap, and wherein the second bulk acoustic resonator is disposed closer to the cap than to the substrate.

The difference between the first and second resonant frequencies may be 500 MHz or more, and each of the first and second resonant frequencies may be higher than 3 GHz.

The bandwidth may cover at least a frequency range of 3.3 GHz or higher and 3.8 GHz or less.

The second bulk acoustic resonator may be electrically connected between the first bulk acoustic resonator and a ground.

The bulk acoustic resonator package may further include a third bulk acoustic resonator comprising a first electrode, a piezoelectric layer, and a second electrode stacked in the direction in which the substrate and the cap face each other, and disposed between the substrate and the cap, wherein a third resonant frequency of the third bulk acoustic resonator may be higher than the second resonant frequency of the second bulk acoustic resonator.

The third bulk acoustic resonator may be connected in series to an inductor, and may be electrically connected between the first bulk acoustic resonator and the ground.

A node via may electrically connect the first and second bulk acoustic resonators and extend in the direction in which the substrate and the cap face each other.

The bulk acoustic resonator package may further include a first cavity located between the substrate and the first bulk acoustic resonator, and a second cavity located between the cap and the second bulk acoustic resonator.

One of the first and second bulk acoustic resonators may further include a mass addition layer to be thicker than the other, and a thickness of the mass addition layer may be at least double a sum of thicknesses of the first and second electrodes of the one of the first and second bulk acoustic resonators.

In another general aspect, a bulk acoustic resonator package includes a substrate, a cap, and first and second bulk acoustic resonators each including a first electrode, a piezoelectric layer, and a second electrode stacked in a direction in which the substrate and the cap face each other, and disposed between the substrate and the cap, wherein the first bulk acoustic resonator is disposed closer to the substrate than to the cap, wherein the second bulk acoustic resonator is disposed closer to the cap than to the substrate, wherein one of the first and second bulk acoustic resonators further includes a mass addition layer to be thicker than the other, and a thickness of the mass addition layer is at least double the sum of the thicknesses of the first and second electrodes of the one of the first and second bulk acoustic resonators.

The bulk acoustic resonator package may further include a cavity disposed further away from the other of the first and second bulk acoustic resonators than the one of the first and second bulk acoustic resonators, wherein the mass addition layer may include a metal material and may be disposed between the cavity and the piezoelectric layer of the one of the first and second bulk acoustic resonators.

The mass addition layer may include a metal material and may be in contact with one or more of the first and second electrodes of the one of the first and second bulk acoustic resonators.

A portion of the mass addition layer may be disposed between the piezoelectric layer of the one of the first and second bulk acoustic resonators and the substrate, and another portion of the mass addition layer may be disposed between the cap and the piezoelectric layer of the one of the first and second bulk acoustic resonators.

The sum of the thicknesses of the first and second electrodes of the one of the first and second bulk acoustic resonators may be 400 nm or less.

Each of a resonant frequency of the first bulk acoustic resonator and a resonant frequency of the second bulk acoustic resonator may be higher than 3 GHz.

In another general aspect, a bulk acoustic resonator package includes a first bulk acoustic resonator disposed on an upper surface of a substrate, a node via electrically connecting the first bulk acoustic resonator and a ground, a second bulk acoustic resonator facing the first bulk acoustic resonator and disposed on a lower surface of a cap coupled to the substrate, wherein the second bulk acoustic resonator is electrically connected between the node via and the ground.

A difference between a sum of thicknesses of electrodes of the first and second bulk acoustic resonators may be two or more.

A difference between a resonant frequency of the first and second bulk acoustic resonators may be 200 MHz or more.

The node via may extend in a direction in which the substrate and the cap face each other.

Other features and aspects will be apparent from the following detailed description, the drawings, and the claims.

### BRIEF DESCRIPTION OF DRAWINGS

FIG. 1A is a circuit diagram illustrating a bulk acoustic resonator package according to an example embodiment in the present disclosure.

FIG. 1B is a graph illustrating a bandwidth based on first and second resonant frequencies and first and second antiresonant frequencies of a bulk acoustic resonator package according to an example embodiment in the present disclosure.

FIG. 2A is a circuit diagram illustrating a first structure in which a difference between first and second resonant frequencies of a bulk acoustic resonator package is high according to an example embodiment in the present disclosure.

FIG. 2B is a graph illustrating a change in resonant frequency according to an inductor of FIG. 2A.

FIG. 3A is a circuit diagram illustrating a second structure in which a difference between first and second resonant frequencies of a bulk acoustic resonator package is high according to an example embodiment in the present disclosure.

FIG. 3B is a graph illustrating a bandwidth of FIG. 3A.

FIG. 4A is a circuit diagram illustrating a third structure in which a difference between first and second resonant frequencies of a bulk acoustic resonator package is high according to an example embodiment in the present disclosure.

FIG. 4B is a perspective view illustrating a bulk acoustic resonator package according to an example embodiment in the present disclosure.

FIG. 4C is a plan view illustrating a structure in which first and second parts of a bulk acoustic resonator package overlap according to an example embodiment in the present disclosure.

FIG. 4D is a plan view illustrating a first part of a bulk acoustic resonator package according to an example embodiment in the present disclosure.

FIG. 4E is a plan view illustrating a second part of a bulk acoustic resonator package according to an example embodiment in the present disclosure.

FIG. 4F is a side view illustrating a bulk acoustic resonator package according to an example embodiment in the present disclosure.

FIGS. 5A, 5B, 5C, 5D, and 5E are side views illustrating structures having differences between resonant frequencies of first and second bulk acoustic resonators of bulk acoustic resonator packages according to one or more example embodiments in the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element’s relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

An aspect of the present disclosure may provide a bulk acoustic resonator package.

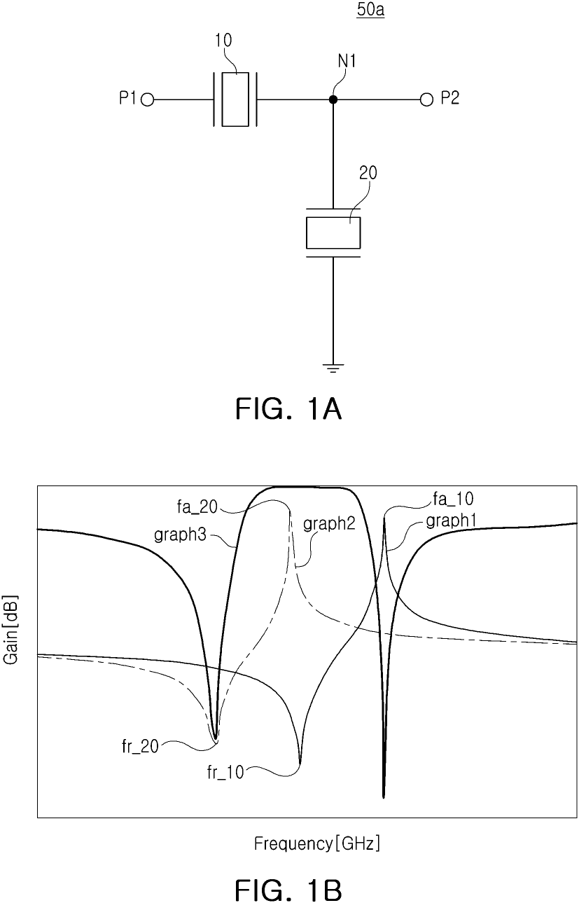

FIG. 1A is a circuit diagram illustrating a bulk acoustic resonator package according to an example embodiment in the present disclosure, and FIG. 1B is a graph illustrating a bandwidth based on first and second resonant frequencies and first and second antiresonant frequencies of a bulk acoustic resonator package according to an example embodiment in the present disclosure.

Referring to FIGS. 1A and 1B, a bulk acoustic resonator package 50a according to an example embodiment in the present disclosure may include a series unit 10 and a shunt unit 20, and may allow a radio frequency (RF) signal to pass or to be blocked between a first RF port P1 and a second RF port P2 according to a frequency of the RF signal. The first RF port P1 and the second RF port P2 may be electrically connected to the series unit 10 so that an external RF signal of the bulk acoustic resonator package 50a may pass through the series unit 10.

The series unit 10 may include one or more series bulk acoustic resonator, and the shunt unit 20 may include one or more shunt bulk acoustic resonator. A node N1 between the series unit 10 and the shunt unit 20 may be implemented as a metal layer. The metal layer may be implemented with a material having a relatively low resistivity, such as gold (Au), gold-tin (Au-Sn) alloy, copper (Cu), copper-tin (Cu—Sn) alloy, aluminum (Al), aluminum alloy, etc. but the present disclosure is not limited thereto.

The bulk acoustic resonator included in each of the series unit 10 and the shunt unit 20 may convert and inversely convert electrical energy of an RF signal into mechanical energy through piezoelectric properties, and as a frequency of the RF signal is closer to a resonant frequency of the bulk acoustic resonator, an energy transfer rate between a plurality of electrodes may increase, and as the frequency of the RF signal is closer to an antiresonant frequency of the bulk acoustic resonator, the energy transfer rate between a plurality of electrodes may significantly decrease. The antiresonant frequency of the bulk acoustic resonator may be higher than the resonant frequency of the bulk acoustic resonator.

For example, the bulk acoustic resonator included in each of the series unit 10 and the shunt unit 20 may be a film bulk acoustic resonator (FBAR) or a solidly mounted resonator (SMR) type resonator. The FBAR may include a cavity, and the SMR may not include a cavity.

The series unit 10 may be electrically connected in series between the first RF port P1 and the second RF port P2, and as the frequency of the RF signal is closer to a first resonant frequency fr_10, a pass rate of the RF signal between the first RF port P1 and the second RF port P2 may increase, and as the frequency of the RF signal is closer to a first antiresonant frequency fa 10, the pass rate of the RF signal between the first RF port P1 and the second RF port P2 may decrease. The series unit 10 may have a frequency characteristic (graph1) in which the first antiresonant frequency fa_10 is higher than the first resonant frequency fr_10.

The shunt unit 20 may be electrically shunt-connected between the series unit 10 and a ground, and as the frequency of the RF signal is closer to a second resonant frequency fr_20, the pass rate of the RF signal toward the ground may increase, and as the frequency of the RF signal is closer to a second antiresonant frequency fa_20, a pass rate of the RF signal toward the ground may decrease. The shunt unit 20 may have a frequency characteristic (graph2) in which the second antiresonant frequency fa_20 is higher than the second resonant frequency fr_20.

In the bulk acoustic resonator, a difference between the resonant frequency and the antiresonant frequency may be determined based on kt² (electromechanical coupling factor), which is a physical characteristic of the bulk acoustic resonator, and kt² may be determined based on the size, thickness, and shape of the bulk acoustic resonator.

The pass rate of the RF signal between the first RF port P1 and the second RF port P2 may decrease as the pass rate of the RF signal toward the ground increases, and may increase as the pass rate of the RF signal toward the ground decreases. That is, the pass rate of the RF signal between the first RF port P1 and the second RF port P2 may decrease as the frequency of the RF signal is closer to the second resonant frequency fr_20 of the shunt unit 20 or closer to the first antiresonant frequency fa_10 of the series unit 10.

Since the antiresonant frequency is higher than the resonant frequency, the bulk acoustic resonator package 50a may have a frequency characteristic (graph 3) forming a pass bandwidth formed by the lowest frequency corresponding to the second resonant frequency fr_20 of the shunt unit 20 and the highest frequency corresponding to the first antiresonant frequency fa_10 of the series unit 10. Alternatively, the bulk acoustic resonator package 50a may have a frequency characteristic (graph 3) forming a stop bandwidth formed with the lowest frequency corresponding to the first resonant frequency fr_10 of the series unit 10 and the highest frequency corresponding to the second antiresonant frequency fa_20 of the shunt unit 20. The pass bandwidth and the stop bandwidth may be widened as a difference between the first resonant frequency fr_10 and the second resonant frequency fr_20 increases.

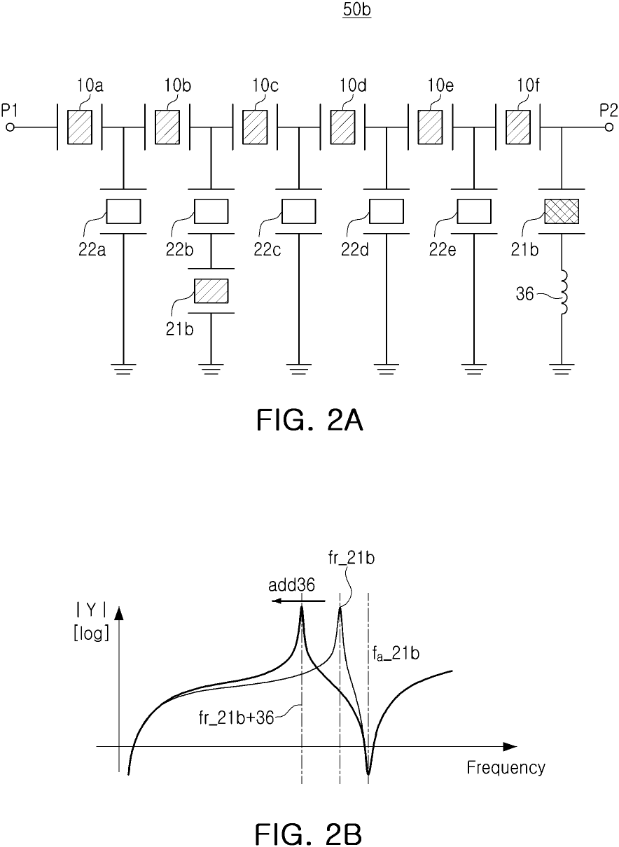

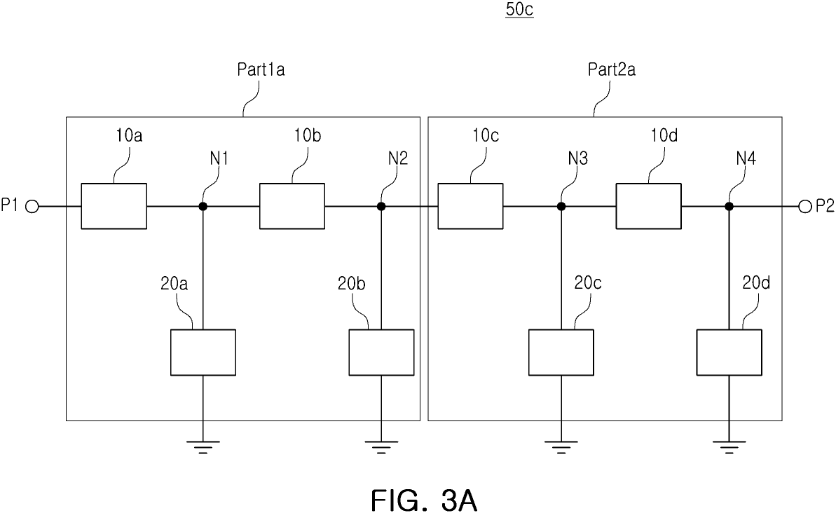

FIG. 2A is a circuit diagram illustrating a first structure in which a difference between first and second resonant frequencies of a bulk acoustic resonator package is high according to an example embodiment in the present disclosure, and FIG. 2B is a graph illustrating a change in resonant frequency according to an inductor of FIG. 2A.

Referring to FIG. 2A, a bulk acoustic resonator package 50b according to an example embodiment in the present disclosure may include a series unit including first bulk acoustic resonators 10a, 10b, 10c, 10d, 10e, and 10f and a shunt unit including second bulk acoustic resonators 22a, 22b, 22c, 22d, and 22e.

For example, the shunt unit may further include a third bulk acoustic resonator 21b, and the third resonant frequency of the third bulk acoustic resonator 21b may be higher than a second resonant frequency of the second bulk acoustic resonators 22a, 22b, 22c, 22d, and 22e.

Accordingly, since the third bulk acoustic resonator 21b having the third resonant frequency may reduce losses (e.g., insertion loss and return loss) within the bandwidth, an optimal difference between the first resonant frequency of the first bulk acoustic resonators 10a, 10b, 10c, 10d, 10e, and 10f and the second resonant frequency of the second bulk acoustic resonators 22a, 22b, 22c, 22d, and 22e may be further increased. Accordingly, the bulk acoustic resonator package 50b may have a wider bandwidth as the difference between the first and second resonant frequencies increases.

For example, the third bulk acoustic resonator 21b may be connected in series to an inductor 36. For example, the inductor 36 may be included in or disposed outside of the bulk acoustic resonator package 50b (e.g., an electronic device substrate on which the bulk acoustic resonator package is disposed).

Referring to FIG. 2B, a resonant frequency fr_21b+36 of a combination of the third bulk acoustic resonator and the inductor may be lower than a resonant frequency fr_21b of the third bulk acoustic resonator, and an antiresonant frequency of the third bulk acoustic resonator fa_21b may be substantially equal to an antiresonant frequency of the combination of the third bulk acoustic resonator and the inductor. FIG. 2B illustrates admittance Y according to a frequency.

For example, the third resonant frequency of the third bulk acoustic resonator 21b may be higher than the second resonant frequency of the second bulk acoustic resonators 22a, 22b, 22c, 22d, and 22e, and the resonant frequency of the combination of the third bulk acoustic resonator 21b and the inductor 36 may be located close to the second resonant frequency.

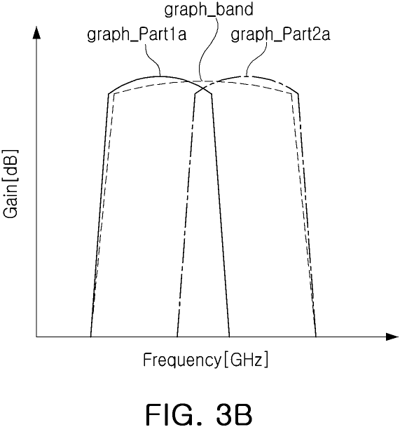

FIG. 3A is a circuit diagram illustrating a second structure in which a difference between first and second resonant frequencies of a bulk acoustic resonator package is high according to an example embodiment in the present disclosure, and FIG. 3B is a graph illustrating a bandwidth of FIG. 3A.

Referring to FIG. 3A, a bulk acoustic resonator package 50c according to an example embodiment in the present disclosure may include a first part Part1a and a second part Part2a, the first part Part1a may include first bulk acoustic resonators 10a and 10b and second bulk acoustic resonators 20a and 20b, and the second part Part2a may include first bulk acoustic resonators 10c and 10d and second bulk acoustic resonator 20c and 20d.

Referring to FIG. 3B, a center frequency of a first bandwidth graph_Part1a of the first part may be lower than a center frequency of a second bandwidth graph_Part2a of the second part and a bandwidth graph band of the bulk acoustic resonator package may cover the first and the second bandwidths graph_Part1a and graph_Part2a, so that an effective bandwidth may be widened.

A second resonant frequency of the second bulk acoustic resonators 20a and 20b may be lower than a fifth resonant frequency of the second bulk acoustic resonators 20c and 20d, and a first resonant frequency of the first bulk acoustic resonators 10c and 10d may be higher than a fourth resonant frequency of the first bulk acoustic resonators 10a and 10b. Accordingly, a difference between the first and second resonant frequencies may be large.

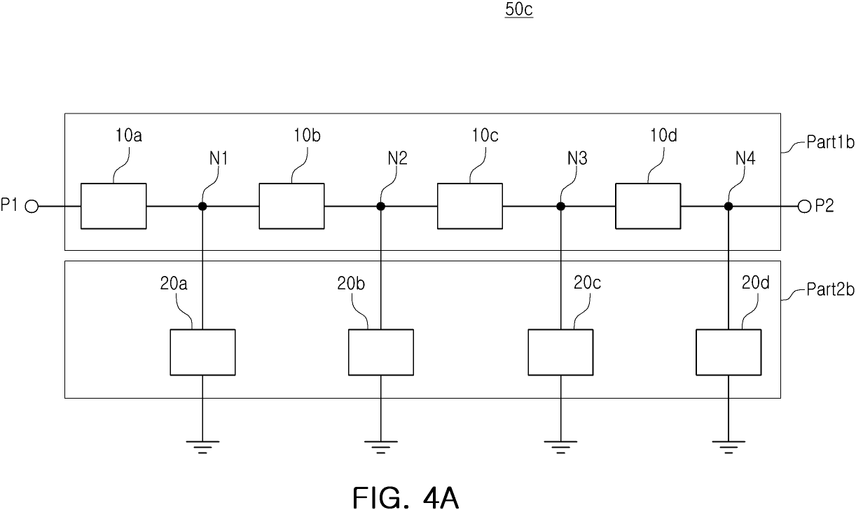

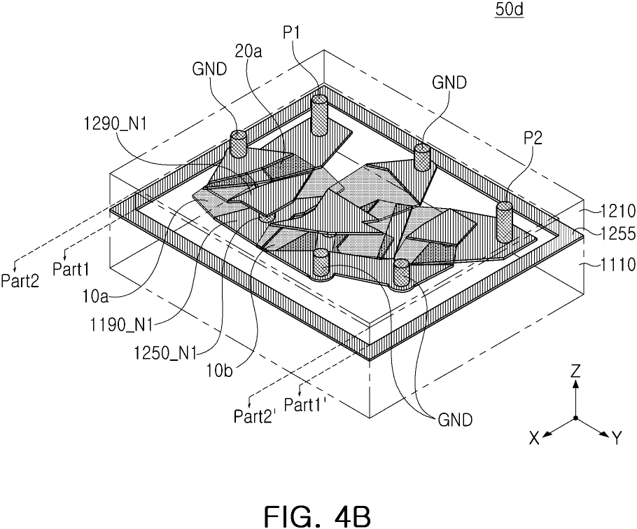

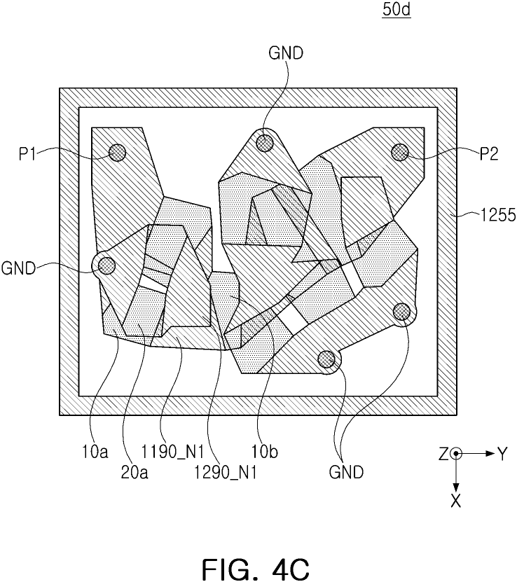

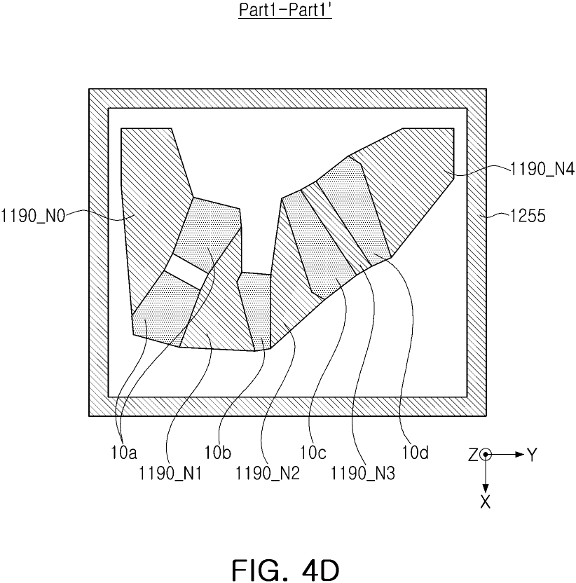

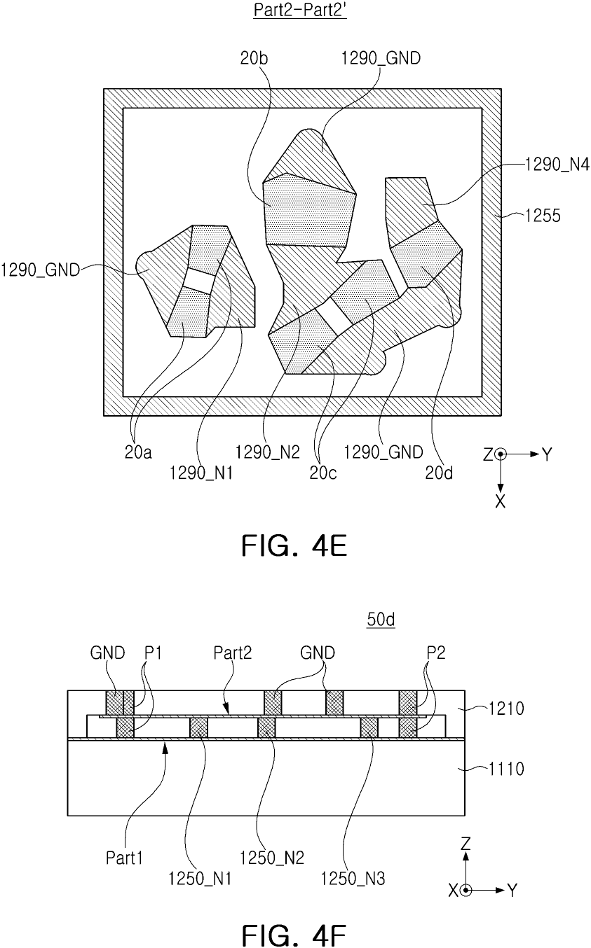

FIG. 4A is a circuit diagram illustrating a third structure in which a difference between first and second resonant frequencies of a bulk acoustic resonator package is high according to an example embodiment in the present disclosure.

Referring to FIG. 4A, a bulk acoustic resonator package 50c according to an example embodiment in the present disclosure may include a first part Part1b and a second part Part2b, and the first part Part1b may include first bulk acoustic resonators 10a, 10b, 10c, and 10d, and the second part Part2b may include second bulk acoustic resonators 20a, 20b, 20c, and 20d.

Nodes N1, N2, N3, and N4 may electrically connect the first bulk acoustic resonators 10a, 10b, 10c, and 10d to the second bulk acoustic resonators 20a, 20b, 20c, and 20d, and the second bulk acoustic resonators 20a, 20b, 20c, and 20d may be electrically connected between the first bulk acoustic resonators 10a, 10b, 10c, and 10d and a ground.

A difference between a first resonant frequency of the first bulk acoustic resonators 10a, 10b, 10c, and 10d and a second resonant frequency of the second bulk acoustic resonators 20a, 20b, 20c, and 20d may be large and may exceed 200 MHz.

FIG. 4B is a perspective view illustrating a bulk acoustic resonator package according to an example embodiment in the present disclosure, FIG. 4C is a plan view illustrating a structure in which first and second parts of a bulk acoustic resonator package overlap according to an example embodiment in the present disclosure, FIG. 4D is a plan view illustrating a first part of a bulk acoustic resonator package according to an example embodiment in the present disclosure, FIG. 4E is a plan view illustrating a second part of a bulk acoustic resonator package according to an example embodiment in the present disclosure, and FIG. 4F is a side view illustrating a bulk acoustic resonator package according to an example embodiment in the present disclosure.

Referring to FIGS. 4B. 4C, 4D, 4E, and 4F, a bulk acoustic resonator package 50d according to an example embodiment in the present disclosure may include a first part Part1 and a second part Part2, the first part Part1 may include a substrate 1110 and first bulk acoustic resonators 10a, 10b, 10c, and 10d, and the second part Part2 may include a cap 1210 and second bulk acoustic resonators 20a, 20b, 20c, and 20d.

The first bulk acoustic resonators 10a, 10b, 10c, and 10d and the second bulk acoustic resonators 20a, 20b, 20c, and 20d may be disposed between the substrate 1110 and the cap 1210 and may have a structure in which a first electrode, a piezoelectric layer, and a second electrode are stacked in a direction (e.g., a Z direction) in which the substrate 1110 and the cap 1210 face each other.

For example, the cap 1210 may include an insulating material such as glass or silicon, and the cap 1210 may have a U-shape in terms of a cross-section perpendicular to an X-Y plane, so that an outer portion of the cap 1210 may protrude downwardly (e.g., in a -Z direction), compared to the center of the cap 1210.

An internal space surrounded by the cap 1210 may be disconnected from the outside of the cap 1210 as the cap 1210 is coupled to the substrate 1110. A coupling member 1255 may couple the cap 1210 to the substrate 1110, and when an additional structure (e.g., a membrane layer) is disposed between the cap 1210 and the substrate 1110, one or more surface of the coupling member 1255 may be bonded to the additional structure to provide coupling force between the cap 1210 and the substrate 1110.

The coupling member 1255 may provide coupling force between the substrate 1110 and the cap 1210. For example, the coupling member 1255 may have a structure in which a plurality of conductive rings is eutectic-bonded or an anodic bonding structure and may hermetically close a space between the substrate 1110 and the cap 1210 and disconnect the space and the outside.

For example, the coupling member 1255 may be disposed closer to the outside than the first bulk acoustic resonators 10a, 10b, 10c, and 10d and the second bulk acoustic resonators 20a, 20b, 20c, and 20d, may surround the first bulk acoustic resonators 10a, 10b, 10c, and 10d and the second bulk acoustic resonators 20a, 20b, 20c, and 20d, and may be electrically connected to a ground.

Referring to FIGS. 4B, 4C, 4D, 4E, and 4F, the first bulk acoustic resonators 10a, 10b, 10c, and 10d may be disposed closer to the substrate 1110 than the cap 1210, and the second bulk acoustic resonator 20a, 20b, 20c, and 20d may be disposed closer to the cap 1210 than the substrate 1110.

Accordingly, a process of adjusting a first resonant frequency of the first bulk acoustic resonators 10a, 10b, 10c, and 10d and a process of adjusting a second resonant frequency of the second bulk acoustic resonators 20a, 20b, 20c, and 20d may be performed separately in a state in which the substrate 1110 is separated from the cap 1210, and thus, the first and second resonant frequencies may be implemented more freely. Accordingly, a difference between the first and second resonant frequencies may be effectively increased.

For example, the resonant frequency of the bulk acoustic resonator may be determined based on an overall thickness of the bulk acoustic resonator, and a thickness change range of the bulk acoustic resonator may be determined based on the thickness of the bulk acoustic resonator. When the difference between the first and second resonant frequencies is high, a difference between an overall thickness of the first bulk acoustic resonators 10a, 10b, 10c, and 10d and an overall thickness of the second bulk acoustic resonators 20a, 20b, 20c, and 20d may be large. As the difference in the overall thickness between the first bulk acoustic resonators 10a, 10b, 10c, and 10d and the second bulk acoustic resonators 20a, 20b, 20c, and 20d increases, a difference between a process and/or a structure of implementing the first bulk acoustic resonators 10a, 10b, 10c, and 10d and a process and/or a structure of implementing the second bulk acoustic resonator 20a, 20b, 20c, and 20d may be large.

The first bulk acoustic resonators 10a, 10b, 10c, and 10d and the second bulk acoustic resonators 20a, 20b, 20c, and 20d having a large difference in the process and/or the structure are disposed dividedly in the substrate 1110 and the cap 1210, so that the bulk acoustic resonator package 50d according to an example embodiment in the present disclosure may efficiently include the first bulk acoustic resonators 10a, 10b, 10c, and 10d and the second bulk acoustic resonators 20a, 20b, 20c, and 20d having different thicknesses, processes, and/or structures. Alternatively, the bulk acoustic resonator package 50d may efficiently include the first bulk acoustic resonators 10a, 10b, 10c, and 10d and the second bulk acoustic resonators 20a, 20b, 20c, and 20d in which the difference between the first and second resonant frequencies exceeds 200 MHz.

For example, the process of controlling the overall thickness of the bulk acoustic resonator may be a process (e.g., an etching process) of reducing the thickness or a process (e.g., a deposition process) of increasing the thickness of the bulk acoustic resonator, and since the thickness increasing process may have a relatively wide thickness control range, compared to the thickness reducing process, and therefore, the thickness increasing process may be advantageous to implement the first and second resonant frequencies having a difference exceeding 200 MHz.

For example, when the thickness difference of the bulk acoustic resonators is implemented so that the difference between the first and second resonant frequencies is high, a time difference of the thickness increasing process may also be large. In this case, the thickness increasing process may be performed in a state in which the substrate 1110 on which the first bulk acoustic resonators 10a, 10b, 10c, and 10d are disposed and the cap 1210 on which the second bulk acoustic resonators 20a, 20b, 20c, and 20d are disposed are separated from each other, and thus, the thickness increasing process may be added to a process requiring relatively little time in an overall process for the substrate 1110 and the overall process for the cap 1210. Accordingly, the bulk acoustic resonator package 50d may be manufactured quickly even if the difference between the first and second resonant frequencies is high.

The node N1 of FIG. 4A may include one or more of a first metal layer 1190_N1, a node via 1250_N1, and a second metal layer 1290_N1 of FIGS. 4B to 4F, the node N2 of FIG. 4A may include one or more of a first metal layer 1190_N2, a node via 1250_N2, and a second metal layer 1290_N2 of FIGS. 4B to 4F, the node N3 of FIG. 4A may include one or more of a first metal layer 1190_N3, a node via 1250_N3, and a second metal layer, and the node N4 of FIG. 4A may include one or more of a first metal layer 1190_N4, a node via, and a second metal layer 1290_N4 of FIGS. 4B to 4F. The first RF port may include a first metal layer 1190_N0.

The first metal layers 1190_N0, 1190_N1, 1190_N2, 1190_N3, and 1190_N4 of the first part Part1 may be disposed closer to the substrate 1110 than the cap 1210, and may be connected to the first electrode or the second electrode of the first bulk acoustic resonators 10a, 10b, 10c, and 10d. The second metal layers 1290_N1, 1290_N2, and 1290_N4 of the second part Part2 may be disposed closer to the cap 1210 than the substrate 1110, and may be connected to the first electrode or the second electrode of the second bulk acoustic resonators 20a, 20b, 20c, and 20d.

A portion 1290_GND of the second metal layer may be connected between the second bulk acoustic resonators 20a, 20b, 20c, and 20d and a ground via GND, and the ground via GND may pass through the cap 1210. The first RF port P1 and the second RF port P2 may also be electrically connected to the first bulk acoustic resonators 10a, 10b, 10c, and 10d and may pass through the cap 1210. For example, the ground via GND may be connected to the ground of the electronic device substrate, and the first RF port P1 and the second RF port P2 may be electrically connected to a power amplifier or antenna disposed on the electronic device substrate. For example, each of the ground via GND, the first RF port P1, and the second RF port P2 may be formed to fill the whole or a portion of a through-hole of the cap 1210 (a side surface of the through-hole). Depending on a design, each of the ground via GND, the first RF port P1, and the second RF port P2 may be formed on the substrate 1110 instead of the cap 1210.

The node vias 1250_N1, 1250_N2, and 1250_N3 may connect the first metal layers 1190_N1, 1190_N2, and 1190_N3 and the second metal layers 1290_N1 and 1290_N2 in a direction (e.g., the Z direction) in which the substrate 1110 and the cap 1210 face each other. Since the nodes N1, N2, N3, and N4 connect the first bulk acoustic resonators 10a, 10b, 10c, and 10d to the second bulk acoustic resonators 20a, 20b, 20c, and 20d, the node vias 1250_N1, 1250_N2, and 1250_N3 may also extend in a direction in which the substrate 1110 and the cap 1210 face each other (e.g., the Z direction) to electrically connect the first bulk acoustic resonators 10a, 10b, and 10c to the second bulk acoustic resonators 20a, 20b, and 20c. For example, the node vias 1250_N1, 1250_N2, and 1250_N3 may be formed simultaneously with the coupling member 1255 and may have the same layer structure as that of a layer structure (e.g., eutectic junction structure, anodic junction structure) of the coupling member 1255.

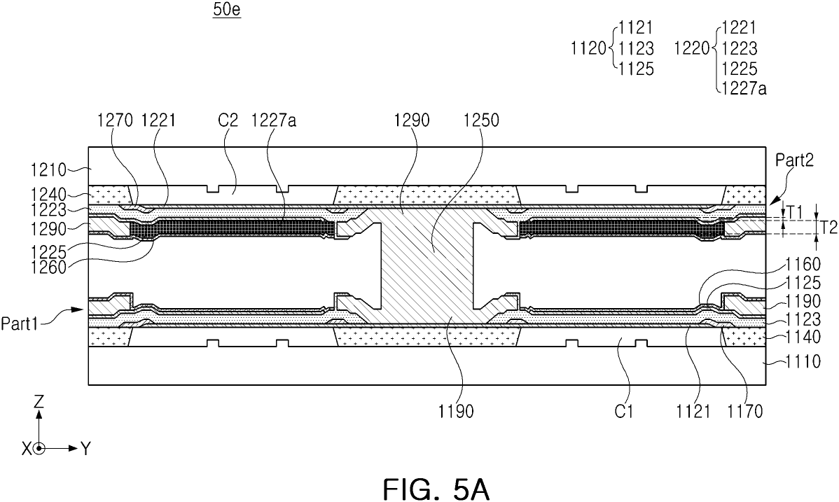

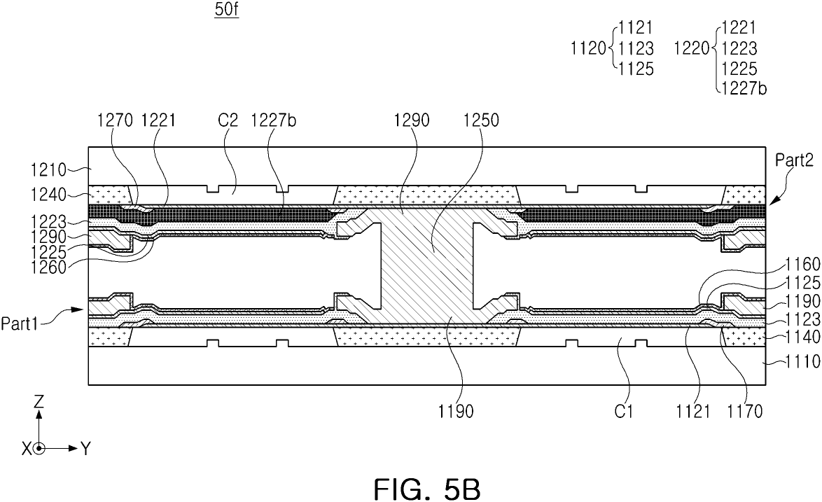

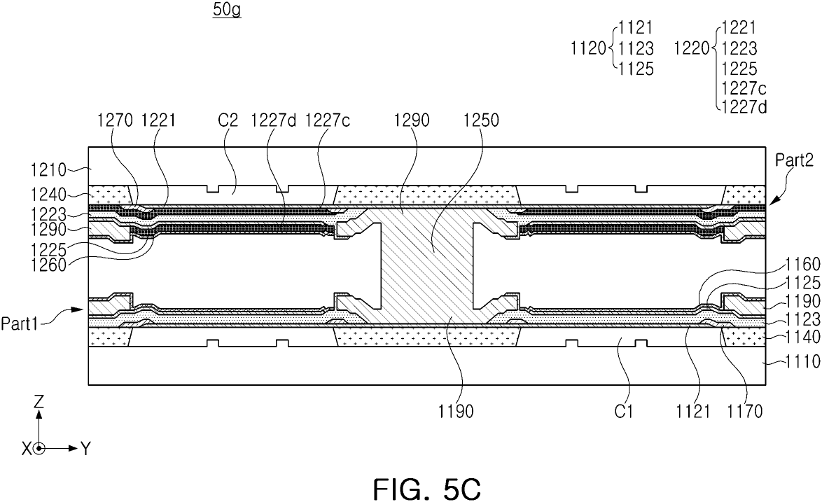

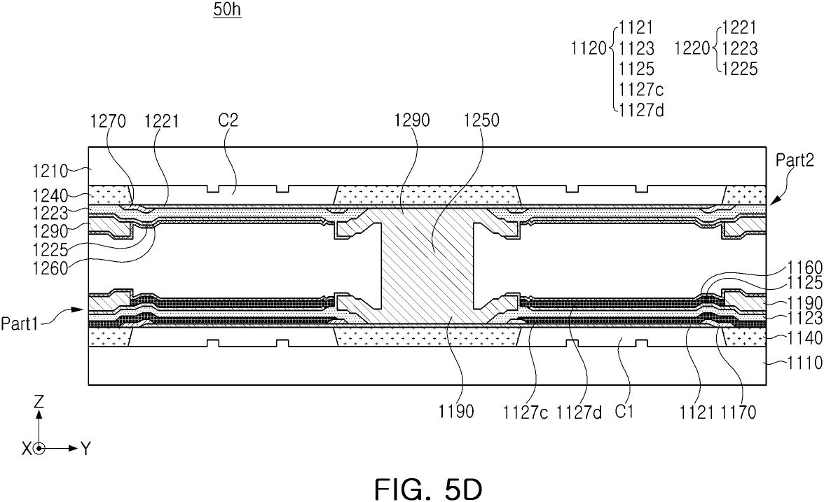

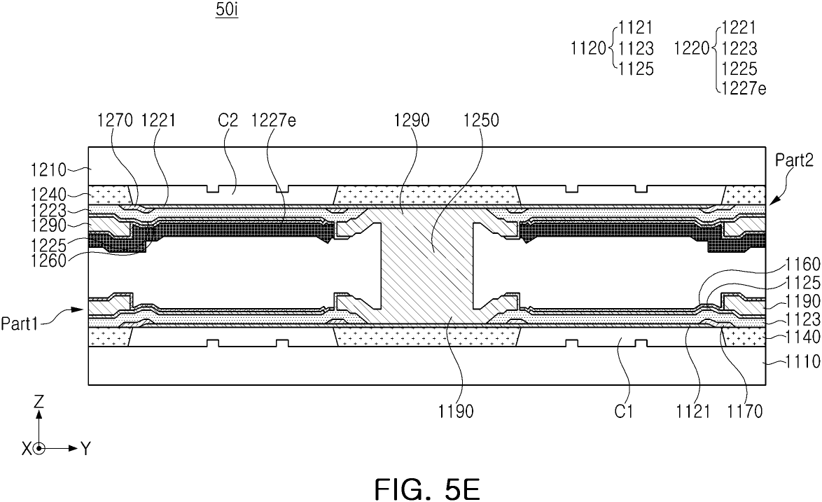

FIGS. 5A to 5E are side views illustrating structures having differences between resonant frequencies of first and second bulk acoustic resonators of bulk acoustic resonator packages according to one or more example embodiments in the present disclosure.

Referring to FIGS. 5A to 5E, bulk acoustic resonator packages 50e, 50f, 50g, 50h, and 50i according to one or more example embodiments in the present disclosure may include a substrate 1110, a first bulk acoustic resonator 1120, a second bulk acoustic resonator 1220, and a cap 1210, and may further include a first cavity C1, a second cavity C2, a first metal layer 1190, a node via 1250, a second metal layer 1290, and one or more of mass addition layers 1127c, 1127d, 1227a, 1227b, 1227c, 1227d, and 1227e. The first metal layer 1190, the node via 1250, and the second metal layer 1290 may be the same as those of FIGS. 4B to 4F.

The substrate 1110 may be a silicon substrate. For example, a silicon wafer or a silicon on insulator (SOI) type substrate may be used as the substrate 1110. An insulating layer may be provided on an upper surface of the substrate 1110 to electrically isolate the substrate 1110 and the first bulk acoustic resonator 1120. In addition, the insulating layer may prevent the substrate 1110 from being etched by an etching gas when the cavity C is formed during a process of manufacturing an acoustic resonator. In this case, the insulating layer may be formed of at least one of silicon dioxide (SiO₂), silicon nitride (Si₃N₄), aluminum oxide (AI2O₃), and aluminum nitride (AIN), and may be formed through any one of chemical vapor deposition, RF magnetron sputtering, and evaporation.

The first cavity C1 may be located between the substrate 1110 and the first bulk acoustic resonator 1120, and may be surrounded by a first support layer 1140. The first support layer 1140 may be formed on the insulating layer, and inside the first support layer 1140, may be disposed in the vicinity of the first cavity C1 and an etch stop portion in a form of surrounding the first cavity C1 and the etch stop portion. The first cavity C1 may be formed as an empty space, and may be formed by removing a portion of a sacrificial layer formed in a process of preparing the first support layer 1140, and the first support layer 1140 may be formed as a remaining portion of the sacrificial layer. For the first support layer 1140, a material such as polysilicon or amorphous silicon that is easy to etch may be used. However, the present disclosure is not limited thereto. The etch stop portion may be disposed along a boundary of the first cavity C1. The etch stop portion may be provided to prevent etching from proceeding beyond a cavity region in the process of forming the first cavity C1.

The second cavity C2 may be located between the cap 1210 and the second bulk acoustic resonator 1220 and may be surrounded by a second support layer 1240. The second support layer 1240 may be disposed in the vicinity of the second cavity C2 and an etch stop portion in a form of surrounding the second cavity C2 and the etch stop portion. The second cavity C2 may be formed as an empty space and may be formed by removing a portion of the sacrificial layer formed in the process of preparing the second support layer 1240, and the second support layer 1240 may be formed as a remaining portion of the sacrificial layer. For the second support layer 1240, a material such as polysilicon or amorphous silicon that is easy to etch may be used. However, the present disclosure is not limited thereto. The etch stop portion may be disposed along a boundary of the second cavity C2. The etch stop portion may be provided to prevent etching from proceeding beyond the cavity region in the process of forming the second cavity C2.

Depending on the design, a membrane layer may be disposed between the first cavity C1 and the first bulk acoustic resonator 1120, and may be disposed between the second cavity C2 and the second bulk acoustic resonator 1220. The membrane layer may be formed of a material that is not easily removed in the process of forming the first and second cavities C1 and C2. For example, when a halide-based etching gas such as fluorine (F) or chlorine (CI) is used to remove a portion (e.g., a cavity region) of the first and second support layers 1140 and 1240, the membrane layer may be formed of a material having low reactivity with the etching gas. In this case, the membrane layer may include one or more of silicon dioxide (SiOs) and silicon nitride (Si₃N₄). In addition, the membrane layer may be formed of a dielectric layer including at least one of materials among magnesium oxide (MgO), zirconium oxide (ZrO₂), aluminum nitride (AIN), lead zirconate titanate (PZT), gallium arsenide (GaAs), hafnium oxide (HfO₂), aluminum oxide (AI2O₃), oxide titanium (TiO₂), and zinc oxide (ZnO), or may be formed of a metal layer including one or more of materials among aluminum (Al), nickel (Ni), chromium (Cr), platinum (Pt), gallium (Ga), and hafnium (Hf). However, the configuration of the present disclosure is not limited thereto.

First and second protective layers 1160 and 1260 are disposed on the surfaces of the first and second bulk acoustic resonators 1120 and 1220 to protect the first and second bulk acoustic resonators 1120 and 1220 from the outside. For example, the first and second protective layers 1160 and 1260 may include any one of silicon dioxide (SiO₂), silicon nitride (Si₃N₄), magnesium oxide (MgO), zirconium oxide (ZrO₂), aluminum nitride (AIN), lead zirconate titanate (PZT), gallium arsenide (GaAs), hafnium oxide (HfO₂), aluminum oxide (AI2O₃), titanium oxide (TiO₂), zinc oxide (ZnO), amorphous silicon (a-Si), and polycrystalline silicon (p-Si), but is not limited thereto.

The first bulk acoustic resonator 1120 may include a first electrode 1121, a piezoelectric layer 1123, and a second electrode 1125, and the second bulk acoustic resonator 1220 may include a first electrode 1221, a piezoelectric layer 1223, and a second electrode 1225.

The first electrodes 1121 and 1221 and the second electrodes 1125 and 1225 may be formed of conductors and may be formed of, for example, gold, molybdenum, ruthenium, iridium, aluminum, platinum, titanium, tungsten, palladium, tantalum, chromium, nickel, or a metal including one or more thereof, but is not limited thereto.

As a material of the piezoelectric layers 1123 and 1223, zinc oxide (ZnO), aluminum nitride (AIN), doped aluminum nitride, lead zirconate titanate, quartz, etc. may be selectively used. The doped aluminum nitride may further include a rare earth metal, a transition metal, or an alkaline earth metal. The rare earth metal may include one or more of scandium (Sc), erbium (Er), yttrium (Y), and lanthanum (La). The transition metal may include one or more of hafnium (Hf), titanium (Ti), zirconium (Zr), tantalum (Ta), and niobium (Nb). The alkaline earth metal may also include magnesium (Mg). The content of elements doped into aluminum nitride (AIN) may be in the range of 0.1 to 30 at%. The piezoelectric layer may be used by doping aluminum nitride (AIN) with scandium (Sc). In this case, a piezoelectric constant may be increased to increase kt² of the acoustic resonator.

Depending on the design, the first and second bulk acoustic resonators 1120 and 1220 may further include first and second insertion layers 1170 and 1270. The first and second insertion layers 1170 and 1270 may be partially placed near the edges of the first and second bulk acoustic resonators 1120 and 1220 so that acoustic impedances at the centers and edges of the first and second bulk acoustic resonators 1120 and 1220 are different from each other. For example, the first and second insertion layers 1170 and 1270 may be formed of silicon dioxide (SiO₂), aluminum nitride (AIN), aluminum oxide (AI2O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), zinc oxide (ZnO), etc. but may be formed of a material different from that of the piezoelectric layers 1123 and 1223.

The mass addition layers 1127c, 1127d, 1227a, 1227b, 1227c, 1227d, and 1227e may cause one of the first and second bulk acoustic resonators 1120 and 1220 to be thicker than the other. For example, the mass addition layers 1127c, 1127d, 1227a, 1227b, 1227c, 1227d, and 1227e may include one or more of metal materials that may be included in the first electrodes 1121 and 1221 and the second electrodes 1125 and 1225.

Referring to FIGS. 5A, 5B, 5C, and 5E, a first resonant frequency of the first bulk acoustic resonator 1120 may be based on a total thickness of the first electrode 1121, the piezoelectric layer 1123, the second electrode 1125, and the first protective layer 1160, and a second resonant frequency of the second bulk acoustic resonator 1220 may be based on a total thickness of the first electrode 1221, the piezoelectric layer 1223, the second electrode 1225, the second protective layer 1260, and the mass addition layers 1227a, 1227b, 1227c, 1227d, and 1227e.

Referring to FIG. 5D, the first resonant frequency of the first bulk acoustic resonator 1120 may be based on a total thickness of the first electrode 1121, the piezoelectric layer 1123, the second electrode 1125, the first protective layer 1160, and the mass addition layers 1127c and 1127d, and the second resonant frequency of the second bulk acoustic resonator 1220 may be based on a total thickness of the first electrode 1221, the piezoelectric layer 1223, the second electrode 1225, and the second protective layer 1260.

While the mass addition layers 1127c and 1127d in FIG. 5D are disposed on the first bulk acoustic resonator 1120 in positions similar to positions of mass addition layers 1227c and 1227d disposed on the second bulk acoustic resonator 1220 in FIG. 5C, the disclosure is not so limited and mass addition layers may be disposed on the first bulk acoustic resonator 1120 in positions similar to positions of mass addition layers 1227a, 1227b, and 1227e disposed on the second bulk acoustic resonator 1220 in FIGS. 5A, 5B, and 5E.

Referring to FIG. 5A, a thickness T2 of the mass addition layer 1227a may be double or more of the sum (double of T1) of the thicknesses of the first and second electrodes of one of the first and second bulk acoustic resonators 1120 and 1220. Accordingly, the overall thickness difference between the first and second bulk acoustic resonators 1120 and 1220 may be large, and a resonant frequency difference between the first and second bulk acoustic resonators 1120 and 1220 may also exceed 200 MHz. For example, the thicknesses T1 and T2 may be measured by analysis using one or more of transmission electron microscopy (TEM), atomic force microscope (AFM), scanning electron microscope (SEM), an optical microscope, and a surface profiler, and may be measured based on a Z-direction virtual line passing through the centers (centers of acoustic resonance) of the first and second bulk acoustic resonators 1120 and 1220.

Since the formation of the mass addition layer 1227a is a process of increasing the thickness of one of the first and second bulk acoustic resonators 1120 and 1220 and may not substantially affect the other, a limit of the thickness of the mass addition layer 1227a may be relatively high compared to the second electrode 1225. Accordingly, the thickness T2 of the mass addition layer 1227a may be four times or more of the thickness T1 of the second electrode 1225.

Since the thickness limit of the mass addition layer 1227a is relatively higher than that of the second electrode 1225, the mass addition layer 1227a may be efficient in implementing the first and second bulk acoustic resonators 1120 and 1220 in which the difference between the first and second resonant frequencies is 500 MHz or more.

For example, some communication bands (e.g., n77 band, n78 band, n79 band) of the 5G communication standard may require a bandwidth of 500 MHz or higher. When the difference between the first and second resonant frequencies is 500 MHz or higher, a bandwidth of some communication bands of the 5G communication standard may be efficiently formed. For example, the bulk acoustic resonator packages 50e, 50f, 50g, 50h, and 50i may form a bandwidth covering a frequency range of 3.3 GHz or higher and 3.8 GHz or less, which is the n78 band. When the highest frequency of the bandwidth is higher, the bulk acoustic resonator packages 50e, 50f, 50g, 50h, and 50i may cover a frequency range of 3.3 GHz or higher and 4.2 GHz or less, which is the n77 band.

For example, a center frequency of the bandwidth of some communication bands of the 5G communication standard may be higher than 3 GHz, and as the center frequency is higher, the bulk acoustic resonator packages 50e, 50f, 50g, 50h, and 50i may become smaller overall. Accordingly, the sum (double of T1) of the thicknesses of the first and second electrodes of one of the first and second bulk acoustic resonators 1120 and 1220 may also be reduced to 400 nm or less.

As the sum (double of T1) of the thicknesses of the first and second electrodes is reduced, an effective thickness control range of the first and second bulk acoustic resonators 1120 and 1220 may also decrease, but the mass addition layers 1127c, 1127d, 1227a, 1227b, 1227c, 1227d, and 1227e may increase the effective thickness control range of the first and second bulk acoustic resonators 1120 and 1220. Accordingly, the bulk acoustic resonator packages 50e, 50f, 50g, 50h, and 50i may efficiently include the first and second bulk acoustic resonators 1120 and 1220 having first and second resonant frequencies higher than 3 GHz. For example, the bulk acoustic resonator packages 50e, 50f, 50g, 50h, and 50i may implement first and second resonant frequencies close to 5.0 GHz to cover the frequency range of 4.4 GHz or higher and 5.0 GHz or less, which is the n79 band.

Referring to FIGS. 5A to 5D, the mass addition layers 1127c, 1127d, 1227a, 1227b, 1227c, and 1227d may be in contact with one or more of the first and second electrodes 1121, 1221, 1125, and 1225 of one of the first and second bulk acoustic resonators 1120 and 1220. When the mass addition layers 1127c, 1127d, 1227a, 1227b, 1227c, 1227d, and 1227e include the same metal material as that of one or more of the first and second electrodes 1121, 1221, 1125, and 1225, the mass addition layers 1127c, 1127d, 1227a, 1227b, 1227c, 1227d, and 1227e may be implemented as a portion of one or more of the first and second electrodes 1121, 1221, 1125, and 1225. Here, there may be no interface between one or more of the first and second electrodes 1121, 1221, 1125, and 1225 and the mass addition layers 1127c, 1127d, 1227a, 1227b, 1227c, 1227d, and 1227e.

Referring to FIG. 5B, the mass addition layer 1227b may be disposed between the piezoelectric layers 1123 and 1223 of one of the first and second bulk acoustic resonators 1120 and 1220 and one of the cavities C1 and C2.

Referring to FIGS. 5C and 5D, a portion of the mass addition layers 1127c, 1127d, 1227c, and 1227d may be disposed between the piezoelectric layers 1123 and 1223 of one of the first and second bulk acoustic resonators 1120 and 1220 and the substrate 1110, and another portion of the mass addition layers 1127c, 1127d, 1227c, and 1227d may be disposed between the piezoelectric layers 1123 and 1223 of one of the first and second bulk acoustic resonators 1120 and 1220 and the cap 1210. A thickness of each of portions of the mass addition layers 1127c, 1127d, 1227c, and 1227d may be the sum (double of T1) or more of the thicknesses of the first and second electrodes.

As set forth above, the bulk acoustic resonator package according to an example embodiment in the present disclosure may have an efficient structure to increase a bandwidth of a filter or increase the center frequency of the bandwidth.

While example embodiments have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic resonator package comprising:
a substrate;
a cap; and
first and second bulk acoustic resonators each comprising a first electrode, a piezoelectric layer, and a second electrode stacked in a direction in which the substrate and the cap face each other, and disposed between the substrate and the cap,
wherein the first and second bulk acoustic resonators form a bandwidth based on first and second resonant frequencies different from each other and first and second antiresonant frequencies different from each other,
wherein a difference between the first and second resonant frequencies exceeds 200 MHz,
wherein the first bulk acoustic resonator is disposed closer to the substrate than to the cap, and
wherein the second bulk acoustic resonator is disposed closer to the cap than to the substrate.

2. The bulk acoustic resonator package of claim 1, wherein the difference between the first and second resonant frequencies is 500 MHz or more, and each of the first and second resonant frequencies is higher than 3 GHz.

3. The bulk acoustic resonator package of claim 1, wherein the bandwidth covers at least a frequency range of 3.3 GHz or higher and 3.8 GHz or less.

4. The bulk acoustic resonator package of claim 1, wherein the second bulk acoustic resonator is electrically connected between the first bulk acoustic resonator and a ground.

5. The bulk acoustic resonator package of claim 4, further comprising:
a third bulk acoustic resonator comprising a first electrode, a piezoelectric layer, and a second electrode stacked in the direction in which the substrate and the cap face each other, and disposed between the substrate and the cap,
wherein a third resonant frequency of the third bulk acoustic resonator is higher than the second resonant frequency of the second bulk acoustic resonator.

6. The bulk acoustic resonator package of claim 5, wherein the third bulk acoustic resonator is connected in series to an inductor, and is electrically connected between the first bulk acoustic resonator and the ground.

7. The bulk acoustic resonator package of claim 1, wherein a node via electrically connects the first and second bulk acoustic resonators and extends in the direction in which the substrate and the cap face each other.

8. The bulk acoustic resonator package of claim 1, further comprising:
a first cavity located between the substrate and the first bulk acoustic resonator; and
a second cavity located between the cap and the second bulk acoustic resonator.

9. The bulk acoustic resonator package of claim 1, wherein
one of the first and second bulk acoustic resonators further comprises a mass addition layer to be thicker than the other, and
a thickness of the mass addition layer is at least double a sum of thicknesses of the first and second electrodes of the one of the first and second bulk acoustic resonators.

10. A bulk acoustic resonator package comprising:
a substrate;
a cap; and
first and second bulk acoustic resonators each comprising a first electrode, a piezoelectric layer, and a second electrode stacked in a direction in which the substrate and the cap face each other, and disposed between the substrate and the cap,
wherein the first bulk acoustic resonator is disposed closer to the substrate than to the cap,
wherein the second bulk acoustic resonator is disposed closer to the cap than to the substrate,
wherein one of the first and second bulk acoustic resonators further comprises a mass addition layer to be thicker than the other, and
wherein a thickness of the mass addition layer is at least double a sum of the thicknesses of the first and second electrodes of the one of the first and second bulk acoustic resonators.

11. The bulk acoustic resonator package of claim 10, further comprising:
a first cavity located between the substrate and the first bulk acoustic resonator; and
a second cavity located between the cap and the second bulk acoustic resonator.

12. The bulk acoustic resonator package of claim 10, further comprising:
a cavity disposed further away from the other of the first and second bulk acoustic resonators than the one of the first and second bulk acoustic resonators,
wherein the mass addition layer comprises a metal material and is disposed between the cavity and the piezoelectric layer of the one of the first and second bulk acoustic resonators.

13. The bulk acoustic resonator package of claim 10, wherein the mass addition layer comprises a metal material and is in contact with one or more of the first and second electrodes of the one of the first and second bulk acoustic resonators.

14. The bulk acoustic resonator package of claim 10, wherein
a portion of the mass addition layer is disposed between the piezoelectric layer of the one of the first and second bulk acoustic resonators and the substrate, and
another portion of the mass addition layer is disposed between the cap and the piezoelectric layer of the one of the first and second bulk acoustic resonators.

15. The bulk acoustic resonator package of claim 10, wherein the sum of the thicknesses of the first and second electrodes of the one of the first and second bulk acoustic resonators is 400 nm or less.

16. The bulk acoustic resonator package of claim 10, wherein each of a resonant frequency of the first bulk acoustic resonator and a resonant frequency of the second bulk acoustic resonator is higher than 3 GHz.

17. A bulk acoustic resonator package comprising:
a first bulk acoustic resonator disposed on an upper surface of a substrate;
a node via electrically connecting the first bulk acoustic resonator and a ground;
a second bulk acoustic resonator facing the first bulk acoustic resonator and disposed on a lower surface of a cap coupled to the substrate,
wherein the second bulk acoustic resonator is electrically connected between the node via and the ground.

18. The bulk acoustic resonator package of claim 17, wherein a difference between a sum of thicknesses of electrodes of the first and second bulk acoustic resonators is two or more.

19. The bulk acoustic resonator package of claim 17, wherein a difference between a resonant frequency of the first and second bulk acoustic resonators is 200 MHz or more.

20. The bulk acoustic resonator package of claim 17, wherein the node via extends in a direction in which the substrate and the cap face each other.
